(19) United States
(12) Patent Application Publication
(10) Pub. No.: US 2013/0153914 A1
(43) Pub. Date: Jun. 20, 2013

(54) ORGANIC LIGHT-EMITTING DISPLAY DEVICE AND METHOD OF MANUFACTURING THE SAME

(71) Applicants: Chun-Gi You, Yongin-City (KR); Joon-Hoo Choi, YongiN-City (KR)

(72) Inventors: Chun-Gi You, Yongin-City (KR); Joon-Hoo Choi, YongiN-City (KR)

(21) Appl. No.: 13/495,206

(22) Filed: Jun. 13, 2012

(30) Foreign Application Priority Data
Dec. 16, 2011 (KR) 10-2011-0136569

(51) Int. Cl. H01L 27/15; H01L 33/08

(52) U.S. Cl. 257/72; 438/23; 257/E27.121; 257/E33.053

(57) ABSTRACT

An organic light-emitting display device includes a thin film transistor on a substrate, a first wiring and a second wiring overlapping each other, the first and second wirings being at different heights relative to the substrate and being connected to the thin film transistor, and a plurality of insulating layers between the first wiring and the second wiring.

### CROSS-REFERENCE TO RELATED PATENT APPLICATION

This application claims the benefit of Korean Patent Application No. 10-2011-0136569, filed on Dec. 16, 2011, in the Korean Intellectual Property Office, the disclosure of which is incorporated herein in its entirety by reference.

### BACKGROUND

1. Field

Example embodiments relate to an organic light-emitting display device having an improved wiring structure that may easily prevent generation of a short circuit, and a method of manufacturing the organic light-emitting display device.

2. Description of the Related Art

In general, organic light-emitting display devices include a thin film transistor (TFT), an electroluminescence (EL) device that is driven by the TFT and forms an image, and the like. In other words, if a current is supplied to the EL device through the TFT, light-emission occurs in the EL device, thereby forming an image. Meanwhile, in the organic light-emitting display device, various lines, i.e., wires, connected to the TFT are formed in a plurality of layers. For example, a power voltage supply line, i.e., an ELVdd line, may be connected to the TFT.

### SUMMARY

Example embodiments provide an organic light-emitting display device having an improved structure that may easily prevent generation of a short circuit, and a method of manufacturing the organic light-emitting display device.

According to example embodiments, there is provided an organic light-emitting display device, including a thin film transistor on a substrate, first wiring and a second wiring overlapping each other, the first and second wirings being at different heights relative to the substrate and being connected to the thin film transistor, and a plurality of insulating layers between the first wiring and the second wiring.

The first wiring may be a global control line, and the second wiring may be a power voltage supply line.

The global control line may be at a same layer level as an active layer of the thin film transistor.

The global control line may be formed of polysilicon.

The global control line and the active layer of the thin film transistor may have a substantially same thickness and include a substantially same material.

A top surface of the power voltage supply line may be substantially level with top surfaces of source and drain electrodes of the thin film transistor.

A distance between a bottom surface of the first wiring and a top surface of the second wiring may equal a distance between a bottom surface of an active layer of the thin film transistor and a top surface of a drain electrode of the thin film transistor.

The thin film transistor may be spaced apart horizontally from each of the first and second wirings.

The plurality of insulating layers may be stacked on top of each other directly between the first wiring and the second wiring.

A total thickness of the plurality of insulating layers along a vertical direction may equal a distance between a top surface of an active layer of the thin film transistor and a bottom surface of a horizontal portion of a drain electrode of the thin film transistor.

According to example embodiments, there is provided a method of manufacturing an organic light-emitting display device, the method including forming a first wiring connected to a thin film transistor of a pixel on a substrate, forming a plurality of insulating layers on the first wiring, and forming a second wiring on the plurality of insulating layers, the second wiring overlapping the first wiring and being connected to the thin film transistor.

Forming the first and second wiring may include forming a global control line and a power voltage supply line, respectively.

Forming the global control line may include forming the line at a same layer level as an active layer of the thin film transistor.

The global control line and the active layer may be formed of polysilicon.

### BRIEF DESCRIPTION OF THE DRAWINGS

The above and other features and advantages of the example embodiments will become more apparent by describing in detail exemplary embodiments thereof with reference to the attached drawings, in which:

FIG. 1 is a circuit diagram of a pixel in an organic light-emitting display device;

FIG. 2 is a schematic plane view of an organic light-emitting display device;

FIG. 3 is a cross-sectional view of an organic light-emitting display device according to an embodiment; and

FIGS. 4A and 4E are cross-sectional views of stages in a method of manufacturing an organic light-emitting display device according to an embodiment.

### DETAILED DESCRIPTION

Hereinafter, exemplary embodiments of the example embodiments will be described in detail with reference to the attached drawings. Like reference numerals designate like elements throughout the specification. In the description, the detailed descriptions of well-known functions and structures may be omitted so as not to hinder the understanding of the example embodiments.

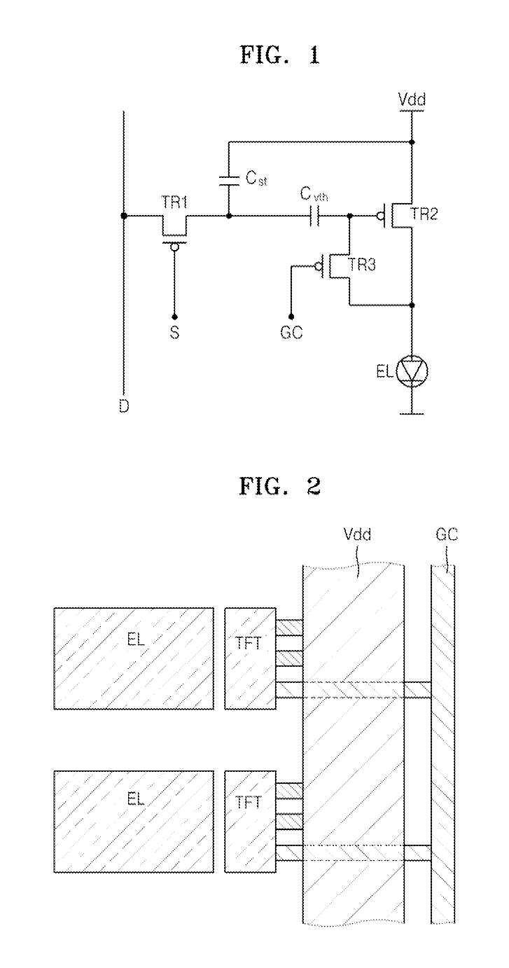

FIG. 1 is a circuit diagram of a pixel of an organic light-emitting display device.

FIG. 2 is a schematic plane view of an organic light-emitting display device.

Referring to FIG. 1, each pixel includes a first thin film transistor TR1 that is a thin film transistor for a switch, a second thin film transistor TR2 that is a thin film transistor for driving, a third thin film transistor TR3 that is a thin film transistor for a compensation signal, capacitors Cst and Cvth that are storage elements, and an electroluminescence (EL) device, e.g., a diode, EL that is driven by the first to third thin film transistors TR1 to TR3. Here, the number of the first to third thin film transistors TR1 to TR3 and the number of the capacitors Cst and Cvth are not limited thereto, and a greater number of thin film transistors and capacitors may be disposed.

Hereinafter, functions of the thin film transistors will be described. First, the first thin film transistor TR1 is driven according to a scan signal applied to a scan line S and transmits a data signal applied to a data line D.

The second thin film transistor TR2 determines an amount of current supplied to the electroluminescence device EL via the power voltage supply line Vdd according to the data signal transmitted via the first thin film transistor TR1.

The third thin film transistor TR3 is connected to a global control line GC to compensate a threshold voltage.

FIG. 2 is a schematic plane view showing the first to third thin film transistors TR1 to TR3, the power voltage supply line Vdd, and the global control line GC that are disposed on a substrate of the organic light-emitting display device.

It is noted that reference character TFT denotes an area where the first to third thin film transistors TR1 to TR3 and the capacitors Cst and Cvth are disposed, and reference character EL denotes the electroluminescence device. It is further noted that while the electroluminescence device EL and the thin film transistor TFT are connected to each other, FIG. 2 illustrates the electroluminescence device EL and the thin film transistor TFT as schematic individual blocks for convenience.

Further, reference character GC denotes a global control line (hereinafter, referred to as a first wiring GC) connected to the third thin film transistor TR3 of the thin film transistor TFT as described above, and the reference character Vdd denotes a power voltage supply line (hereinafter, referred to as a second wiring Vdd).

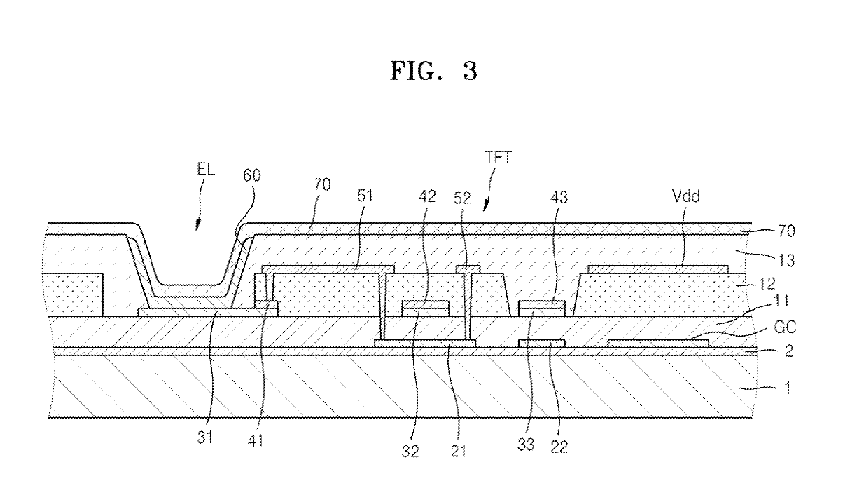

Here, since the first wiring GC is connected to the thin film transistor TFT across a wide area of the second wiring Vdd, a relatively large overlap region between the first wiring GC and the second wiring Vdd may be formed. In order to prevent a potential short circuit in the relatively large overlap region, a plurality of insulating layers may be disposed between the first wiring GC and the second wiring Vdd in the organic light emitting display device of the example embodiments. A detailed description of the insulating layers will be provided below with reference to FIG. 3.

Referring to FIG. 3, a plurality of insulating layers, e.g., a first insulating layer 11 and a second insulating layer 12, are formed between the first wiring GC and the second wiring Vdd. Thus, since the first and second insulating layers 11 and 12, i.e., a number of insulating layers that is twice greater than a number of insulating layers in a conventional organic light emitting display device, are formed between the first wiring GC and the second wiring Vdd, a possibility of a short circuit in the overlap region may be substantially reduced. In addition, since the first wiring GC is formed of the same material at the same layer level as an active layer 21 of the thin film transistor TFT, manufacturing processes may be simplified compared to conventional manufacturing processes.

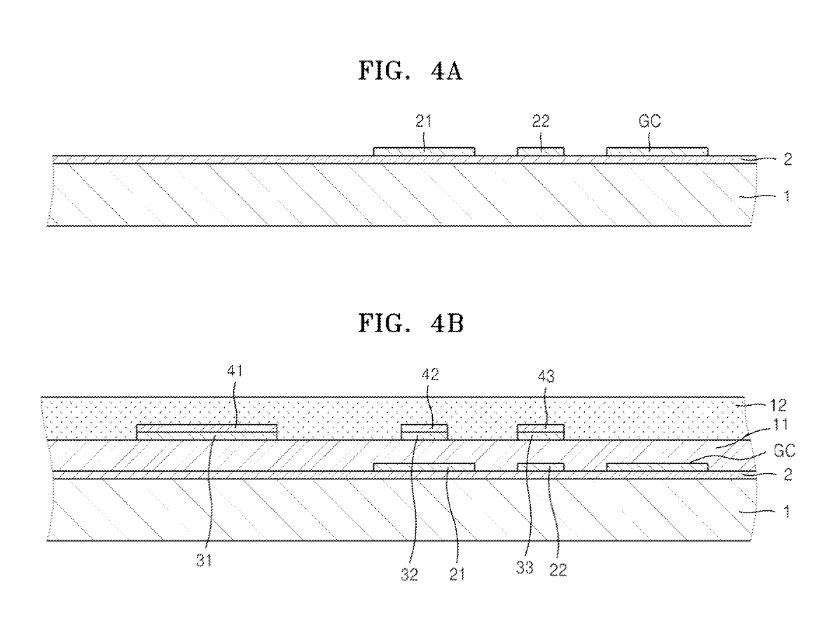

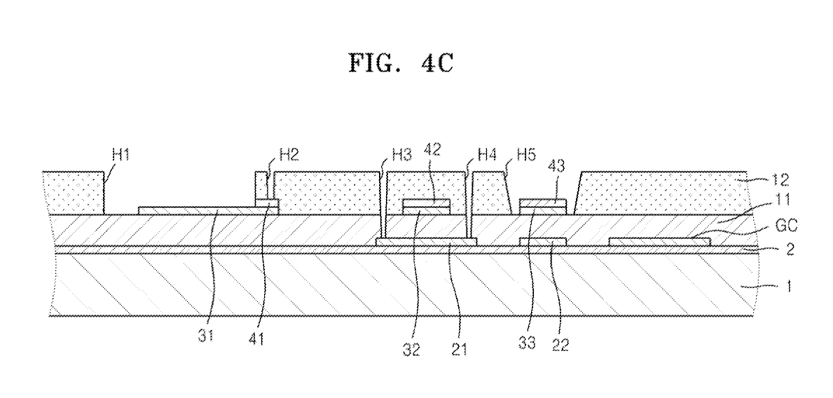

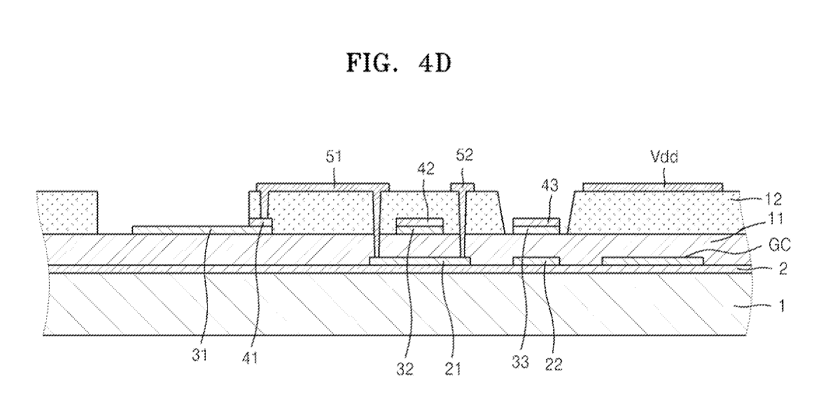

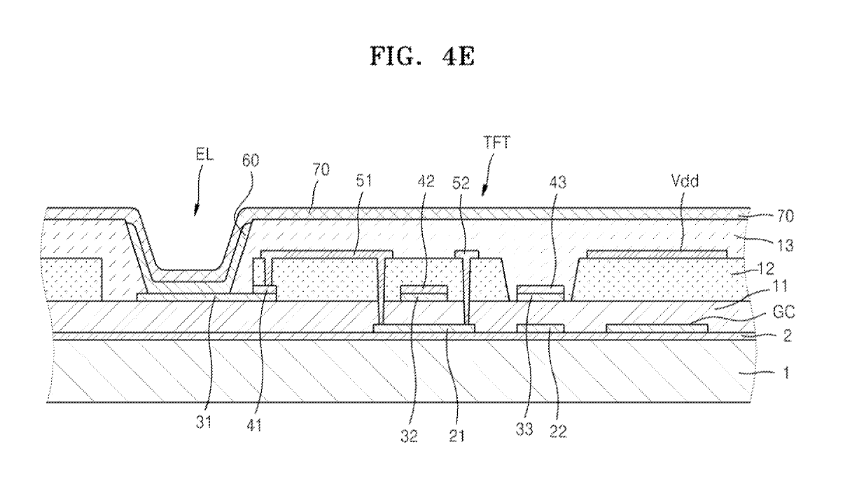

The manufacturing method of the organic light emitting display device with the first and second wirings will be described in detail with reference to FIGS. 4A-4E.

First, as shown in FIG. 4A, a buffer layer 2 is formed on a substrate 1. In addition, the active layer 21 of the thin film transistor TFT, a lower electrode 22 of the capacitor Cst, and the first wiring GC may be formed of the same material, e.g., polysilicon, on the buffer layer 2.

As shown in FIG. 4B, the first insulating layer 11 is formed, metal layers 41, 42, and 43 are sequentially formed on indium tin oxide (ITO) layers 31, 32, and 33, respectively, and the second insulating layer 12 is formed on the first insulating layer 11. In this case, the ITO layer 31 and the metal layer 41 correspond to a pixel electrode of an electroluminescence (EL) device, the ITO layer 32 and the metal layer 42 correspond to a gate electrode of the thin film transistor TFT, and the ITO layer 33 and the metal layer 43 correspond to an upper electrode of the capacitor Cst.

Then, as shown in FIG. 4C, a plurality of holes H1, H2, H3, H4, and H5 are formed in the second insulating layer 12 by using an etching method. Then, as shown in FIG. 4D, source and drain electrodes 51 and 52 of the thin film transistor TFT and the second wiring Vdd may be formed of the same material at the same layer level. Thus, as described above, since a plurality of insulating layers 11 and 12 are formed between the first wiring GC and the second wiring Vdd, a possibility of a short circuit between the first wiring GC and the second wiring Vdd is considerably reduced.

Then, a structure shown in FIG. 4E is obtained by forming a pixel definition layer 13, a light emission layer 60, and an opposite electrode 70 of the EL device.

According to the example embodiments, when a plurality of insulating layers 11 and 12 are disposed between the first wiring GC and the second wiring Vdd, a distance between the first and second wirings GC and Vdd increases, thereby reducing a possibility of a short circuit between the first wiring GC and the second wiring Vdd. In other words, according to the example embodiments, the above-described organic light-emitting display device includes increased insulation between the power voltage supply line and an adjacent overlapping line in a vertical direction. As such, a vertical distance between the overlapping lines may be increased. Accordingly, a possibility of a short circuit between the two overlapping lines may decrease, despite a potential increased overlapping area between the two lines, thereby reducing a percent of defective products.

In contrast, since only a single insulating layer is disposed between the first wiring GC and the second wiring Vdd of a conventional organic light-emitting display device, a possibility that a short circuit may occur between the first wiring GC and the second wiring Vdd is high. That is, as the Vdd line may have a relatively large width compared to other lines, a size of an area where the Vdd line overlaps another line disposed in a different layer may increase, thereby increasing a possibility of a short circuit between the lines, e.g., between the Vdd line and a global control line crossing the Vdd line. As such, the conventional organic light-emitting display devices may have an increased number of defective products due to the short circuited wirings.

While the example embodiments has been particularly shown and described with reference to exemplary embodiments thereof, it will be understood by those of ordinary skill in the art that various changes in form and details may be made therein without departing from the spirit and scope of the example embodiments as defined by the following claims.

What is claimed is:

1. An organic light-emitting display device, comprising:
a thin film transistor on a substrate;
a first wiring and a second wiring overlapping each other, the first and second wirings being at different heights relative to the substrate and being connected to the thin film transistor; and
a plurality of insulating layers between the first wiring and the second wiring.

2. The organic light-emitting display device of claim 1, wherein the first wiring is a global control line, and the second wiring is a power voltage supply line.

3. The organic light-emitting display device of claim 2, wherein the global control line is at a same layer level as an active layer of the thin film transistor.

4. The organic light-emitting display device of claim 3, wherein the global control line is formed of polysilicon.

5. The organic light-emitting display device of claim 3, wherein the global control line and the active layer of the thin film transistor have a substantially same thickness and include a substantially same material.

6. The organic light-emitting display device of claim 3, wherein a top surface of the power voltage supply line is substantially level with top surfaces of source and drain electrodes of the thin film transistor.

7. The organic light-emitting display device of claim 1, wherein a distance between a bottom surface of the first wiring and a top surface of the second wiring equals a distance between a bottom surface of an active layer of the thin film transistor and a top surface of a drain electrode of the thin film transistor.

8. The organic light-emitting display device of claim 1, wherein the thin film transistor is spaced apart horizontally from each of the first and second wirings.

9. The organic light-emitting display device of claim 1, wherein the plurality of insulating layers are stacked on top of each other directly between the first wiring and the second wiring.

10. The organic light-emitting display device of claim 1, wherein a total thickness of the plurality of insulating layers along a vertical directions equals a distance between a top surface of an active layer of the thin film transistor and a bottom surface of a horizontal portion of a drain electrode of the thin film transistor.

11. A method of manufacturing an organic light-emitting display device, the method comprising:
forming a first wiring connected to a thin film transistor of a pixel on a substrate;
forming a plurality of insulating layers on the first wiring; and
forming a second wiring on the plurality of insulating layers, the second wiring overlapping the first wiring and being connected to the thin film transistor.

12. The method of claim 11, wherein forming the first and second wiring includes forming a global control line and a power voltage supply line, respectively.

13. The method of claim 12, wherein forming the global control line includes forming the line at a same layer level as an active layer of the thin film transistor.

14. The method of claim 13, wherein the global control line and the active layer are formed of polysilicon.
